(19) United States
(12) Patent Application Publication
(10) Pub. No.: US 2024/0412918 A1
(43) Pub. Date: Dec. 12, 2024

(54) COIL STRUCTURE AND ELECTRONIC DEVICE

(71) Applicant: BOE Technology Group Co., Ltd., Beijing, (CN)

(72) Inventors: Hao ZHANG, Beijing (CN); Mengyang WEN, Beijing (CN); Libin LIU, Beijing (CN); Shiming SHI, Beijing (CN); Haijun QIU, Beijing (CN)

(21) Appl. No.: 18/696,964

(22) PCT Filed: Aug. 1, 2023
(86) PCT No.: PCT/CN2023/110464

§ 371 Date: Mar. 28, 2024

(30) Foreign Application Priority Data
Sep. 5, 2022 (CN) 202211078870.1

(51) Int. Cl. H01F 27/28; H01F 38/14; H05K 1/02; H05K 1/16

(52) U.S. Cl. CPC H01F 27/2804; H01F 38/14; H05K 1/0281; H05K 1/165; H01F 2038/143

(57) ABSTRACT

The present disclosure provides a coil structure. The coil structure includes: a dielectric substrate; and a coil portion and a first pattern disposed on the dielectric substrate; wherein the first pattern extends through at least a portion of the dielectric substrate along a thickness direction of the dielectric substrate, and the first pattern is not overlapped with the coil portion.

### CROSS-REFERENCE TO RELATED APPLICATIONS

This application is a U.S. national stage of international application No. PCT/CN2023/110464, filed on Aug. 1, 2023, which claims priority to Chinese Patent Application No. 202211078870.1, filed on Sep. 5, 2022, and entitled “COIL STRUCTURE AND ELECTRONIC EQUIPMENT,” the disclosures of which are herein incorporated by reference in their entireties.

### TECHNICAL FIELD

The present disclosure relates to the technical field of electronic devices, and in particular, to a coil structure and an electronic device.

### BACKGROUND

The substrate on which the receiving coil is located is prone to stretching or bending during use, which may easily lead to coil breakage.

### SUMMARY

The present disclosure aims to solve at least one of the technical problems in the prior art by providing a coil structure and an electronic device.

According to some embodiments of the present disclosure, a coil structure is provided. The coil structure includes a dielectric substrate; and a coil portion and a first pattern disposed on the dielectric substrate; wherein the first pattern extends through at least a portion of the dielectric substrate along a thickness direction of the dielectric substrate, and the first pattern is not overlapped with the coil portion.

In some embodiments, the dielectric substrate comprises a first region, a second region, and a third region, the second region surrounding the first region, and the third region surrounding the second region; wherein the coil portion is disposed in the second region, and the first pattern is arranged in both the first region and the third region.

In some embodiments, a first sub-region of the second region is defined between adjacent turns of the coil portion, and the first pattern is arranged in the first sub-region.

In some embodiments, the coil portion has at least one of a square shape, a hexagonal shape, an octagonal shape, or a circular shape.

In some embodiments, an outline of the first pattern has at least one of a linear shape, an I shape, and a circular arc shape.

In some embodiments, the coil structure includes first patterns with two shapes of outline which are respectively a first shape and a second shape, wherein the first patterns are arranged in a fashion of alternating between the first shape and the second shape along a row direction and a column direction of the dielectric substrate.

In some embodiments, the coil portion has a circular shape; wherein,
the first pattern comprises a plurality of first sub-patterns arranged sequentially along a clockwise direction, wherein an outline of the first sub-pattern has a circular arc shape, and the plurality of first sub-patterns are concentric.

In some embodiments, a plurality of the first patterns are arranged, and the first sub-patterns of different first patterns are disposed in one-to-one correspondence.

In some embodiments, the coil structure further includes a light-emitting device; wherein the coil portion comprises a first connecting end and a second connecting end, the first connecting end being connected to a first electrode of the light-emitting device, and the second connecting end being connected to a second electrode of the light-emitting device.

In some embodiments, the coil structure further comprises an insulating layer and a pixel-definition layer that are sequentially disposed on a side, distal from the dielectric substrate, of the coil portion, the pixel-definition layer having an accommodation portion; the light-emitting device comprises the first electrode, a light-emitting layer, and the second electrode, the first electrode being disposed on a side, distal from the coil portion, of the insulating layer, the light-emitting layer being disposed on a side, distal from the insulating layer, of the first electrode and being positioned at least within the accommodation portion of the pixel-definition layer, and the second electrode is positioned on a side, distal from the first electrode, of the light-emitting layer; and
the first connecting end is connected to the first electrode through a first via hole, and the second connecting end is connected to the second electrode through a second via hole; wherein the first via hole runs through the insulating layer, and the second via hole runs through the insulating layer and the pixel-definition layer.

In some embodiments, the first pattern runs through the dielectric substrate along a thickness direction of the dielectric substrate.

In some embodiments, the coil structure is a near field communication antenna or a charging coil.

According to some embodiments of the present disclosure, an electronic device is provided, wherein the electronic device includes the above coil structure and a functional device disposed on the coil structure.

### BRIEF DESCRIPTION OF DRAWINGS

FIG. 1 is a schematic diagram of a coil structure provided by the embodiments of the present disclosure;

FIG. 2a is a schematic diagram of regions on the dielectric substrate shown in FIG. 1;

FIG. 2b is an exemplary schematic diagram of regions on a dielectric substrate;

FIG. 3 is a schematic diagram of another coil structure according to the embodiments of the present disclosure;

FIG. 4 is a schematic diagram of another coil structure according to the embodiments of the present disclosure;

FIG. 5 is a schematic diagram of another coil structure according to the embodiments of the present disclosure;

FIG. 6 is a schematic diagram of another coil structure according to the embodiments of the present disclosure;

FIG. 7 is a schematic diagram of another coil structure according to the embodiments of the present disclosure; and

FIG. 8 is a schematic diagram of a light-emitting device in the embodiments of the present disclosure.

### REFERENCE NUMERALS AND DENOTATIONS THEREOF

dielectric substrate 01; coil portion 10; first pattern 20; first sub-pattern 201; first region Q1; second region Q2; third region Q3; light-emitting device 30; first connecting end 101; second connecting end 102; first electrode 03; second electrode 04; insulating layer 02; pixel-definition layer PDL; light-emitting layer EL; and encapsulation layer 05.

### DETAILED DESCRIPTION

In order to make the purpose, technical solutions, and advantages of the embodiments of the present disclosure clearer, the technical solutions in the embodiments of the present disclosure are clearly and completely described hereafter in conjunction with the accompanying drawings in the embodiments of the present disclosure. It is apparent that the embodiments described are only a portion of the embodiments of the present disclosure and not all of the embodiments. The components of the embodiments of the present disclosure described and illustrated in the accompanying drawings herein may generally be arranged and designed in a variety of different configurations. Accordingly, the following detailed description of the embodiments of the present disclosure provided in the accompanying drawings is not intended to limit the scope of the present disclosure for which protection is claimed, but rather illustrates only selected embodiments of the present disclosure. Based on the embodiments of the present disclosure, all other embodiments obtained by a person skilled in the art without creative labor are within the protection scope of the present disclosure.

Unless otherwise defined, technical or scientific terms used in the present disclosure have the ordinary meaning understood by a person of ordinary skill in the art to which the present disclosure belongs. The terms “first,” “second,” and the like as used in the present disclosure do not indicate any order, number, or significance, but are merely used to distinguish between different components. Similarly, words such as “a,” “an,” or “the” and the like do not indicate a limitation in number, but rather the presence of at least one. Words such as “include” or “comprise” mean that the component or object in front of the word encompasses the component or object and their equivalents enumerated behind the word and does not exclude other components or objects. Words such as “connected to” or “connect with” are not limited to physical or mechanical connections, but may include electrical connections, whether direct or indirect. The words “up,” “down,” “left,” “right”, etc. are used only to indicate relative positional relationships. In the case that the absolute position of the described object is changed, then that relative positional relationship may be changed accordingly.

In the present disclosure, “more than one or a plurality of” refers to two or more. The term “and/or” describes an association relationship of the associated objects, which includes three relationships, e.g., A and/or B may indicate the three cases of: the existence of A alone, the existence of both A and B, and the existence of B alone. The character “/” generally indicates that the front and behind associated objects are in an “or” relationship.

Currently, receiving coils in magnetic induction coils are susceptible to deformation and thus breakage, which affects their function.

In view of this, a coil structure and an electronic device are provided by the embodiments of the present disclosure.

According to a first aspect, the embodiments of the present disclosure provide a coil structure in which a first pattern 20 is provided on a dielectric substrate 01, so as to enhance the deformation capability of the dielectric substrate 01 and improve the tensile property of the dielectric substrate 01. In this way, the coil structure is not prone to coil breakage, even if the coil structure is subjected to some extent of bending or stretching during use, thereby improving the use reliability of the coil. In addition, the present disclosure is also applicable to the need for a shaped design of the dielectric substrate 01.

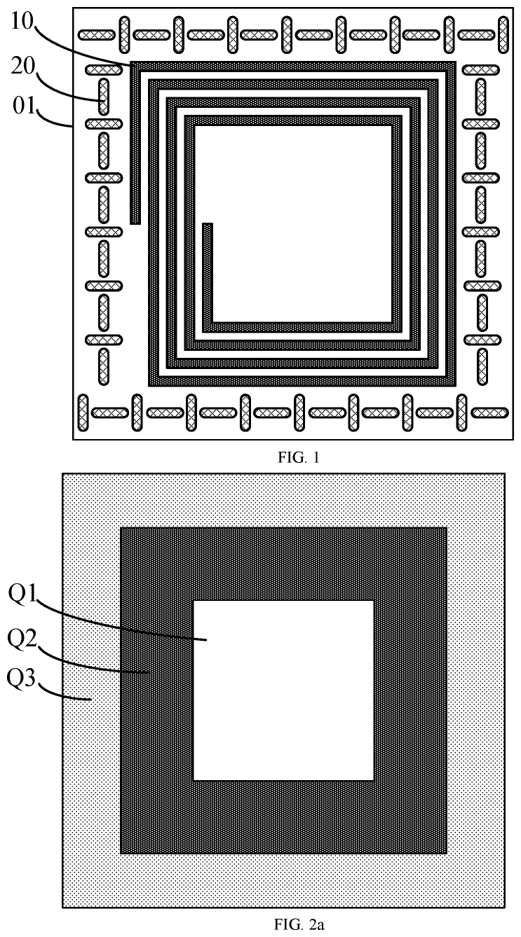

Specifically, FIG. 1 is a schematic diagram of a coil structure according to the embodiments of the present disclosure, as shown in FIG. 1, the coil structure includes a dielectric substrate 01; and a coil portion 10 and a first pattern 20 disposed on the dielectric substrate 01; wherein the first pattern 20 extends through at least a portion of the dielectric substrate 01 along a thickness direction of the dielectric substrate 01, and the first pattern 20 is not overlapped with the coil portion 10. That is, in some embodiments, the first pattern 20 is a blind groove that partially extends through the dielectric substrate 01 or a through groove that completely runs through the dielectric substrate 01. The embodiments of the present disclosure are illustrated by taking that the first pattern 20 is a through groove that completely runs through the dielectric substrate 01 as an example.

In some embodiments, the dielectric substrate 01 is a flexible substrate to facilitate the formation of the first pattern 20; the coil portion 10 includes a coil to receive a current to achieve communication functions, charging functions, and the like. The material of the coil portion 10 includes, but is not limited to, metallic materials such as copper, aluminum, etc. In some preferred embodiments, the material of the coil portion 10 is copper to obtain better electrical properties and a stronger magnetic field.

In FIG. 1, only one coil portion 10 of the coil structure is shown, and the coil portion 10 has a square shape. Of course, it is to be understood that in some embodiments the coil portion 10 is more than one, i.e., the number of coil portions 10 depends on the actual requirements. In some embodiments, the first patterns 20 have a plurality of outline shapes, and the first patterns 20 of the plurality of outline shapes can be obtained by rotating a specific angle. In some embodiments, the first patterns 20 have two kinds of outline shapes, and the outline of one kind of first pattern 20 is obtained by rotating the outline of the other kind of first pattern 20 by 90°, e.g., the outline of one kind of first pattern 20 is “-”, and the outline of the other first pattern 20 is “1”. The first patterns 20 are arranged in a fashion of alternating between the above two shapes along the row direction and the column direction of the dielectric substrate 01. The first pattern 20 is arranged around the coil portion 10 and in the square region surrounded by the coil portion 10, and this arrangement causes the first pattern 20 to be uniformly distributed around and inside the coil portion 10, so that when the coil structure is subjected to a tensile force, due to the provision of the first pattern 20 on the dielectric substrate 01, the inner stress of the dielectric substrate 01 is uniformly dispersed by the first pattern 20, and at the same time, no wire-breaking situation resulting from sudden change of the stress at a specific position will occur, thereby protecting the coil portion 10 and ensuring the electrical performance of the coil structure.

The first pattern 20 extends through at least a portion of the dielectric substrate 01 along the thickness direction of the dielectric substrate 01, i.e., in some embodiments, the first pattern 20 extends partially through the dielectric substrate 01, or in some embodiments, runs completely through the dielectric substrate 01. Of course, it can be appreciated that in the case that the first pattern 20 runs completely through the dielectric substrate 01 as shown in FIG. 1, the amount of stretchability of the dielectric substrate 01 is relatively large, and in the case that the first pattern 20 extends partially through the dielectric substrate 01, the amount of stretchability of the dielectric substrate 01 is relatively small. The first pattern 20 is not overlapping with the coil portion 10, i.e., when forming the first pattern 20, the coil portion 10 is avoided by the first pattern 20, to avoid adversely affecting the electrical properties of the coil portion 10.

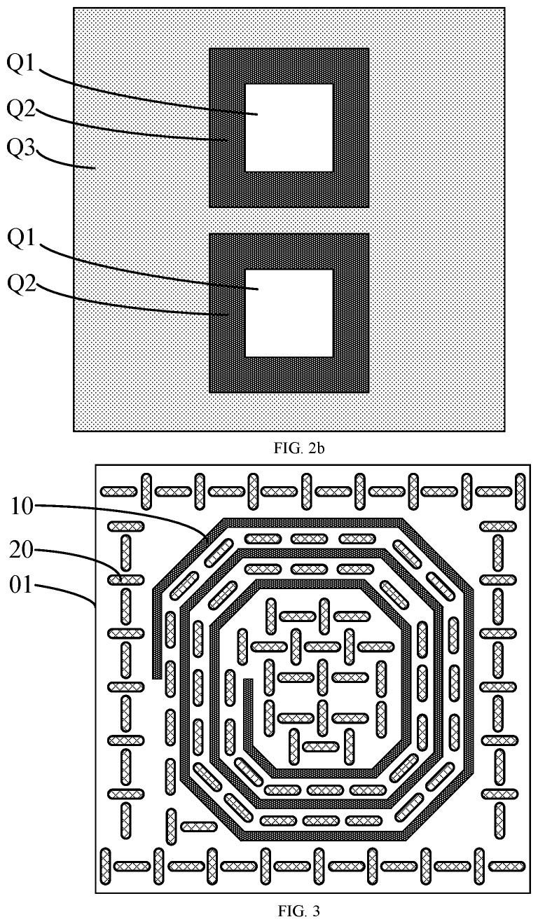

In some embodiments, FIG. 2a is a schematic diagram of regions on the dielectric substrate shown in FIG. 1. As shown in FIGS. 1 and 2a, the dielectric substrate 01 includes a first region Q1, a second region Q2, and a third region Q3, the second region Q2 surrounding the first region Q1, and the third region Q3 surrounding the second region Q2; and the coil portion 10 is disposed in the second region Q2, and the first pattern 20 is disposed in both the first region Q1 and the third region Q3. The region in which the coil portion 10 is located is the second region Q2, the region surrounding the coil portion 10 and the region surrounded by the coil portion 10 are respectively the third region Q3 and the first region Q1, and both the first region Q1 and the third region Q3 are provided with the first pattern 20.

It is noted that in the case that the number of coil portions 10 is plurality, the number of the first regions Q1, the second regions Q2, and the third regions Q3 are not all one. The number of the second regions Q2 and the first regions Q1 depend on the number of coil portions 10, and one second region Q2 surrounds one first region Q1. FIG. 2b is an exemplary schematic diagram of regions on the dielectric substrate, as shown in FIG. 2b, the number of coil portions 10 is two and are respectively a first coil portion 10 (not shown in the figure) and a second coil portion 10 (not shown in the figure), wherein the region in which the first coil portion 10 is located is the second region Q2, the region surrounded by the first coil portion 10 is a first region Q1, the region in which the second coil portion 10 is located is a second region Q2, and the region surrounded by the second coil portion 10 is a first region Q1. That is, there are two first regions Q1 and two second regions Q2 on the dielectric substrate 01, and the remaining regions are the third regions Q3.

In some embodiments, the second region Q2 in which the coil portion 10 is located is the center region of the dielectric substrate 01. In this way, the stress in the dielectric substrate 01 is further evenly dispersed, so that in the case that the stress is released, the dielectric substrate 01 is not prone to warping, deformation, cracking, or the like at the position where the stress is residual.

Of course, it is understood that in some embodiments the first pattern 20 is provided only in the first region Q1 or the third region Q3, and the difference is that the final formed dielectric substrates 01 have different stretchability amounts.

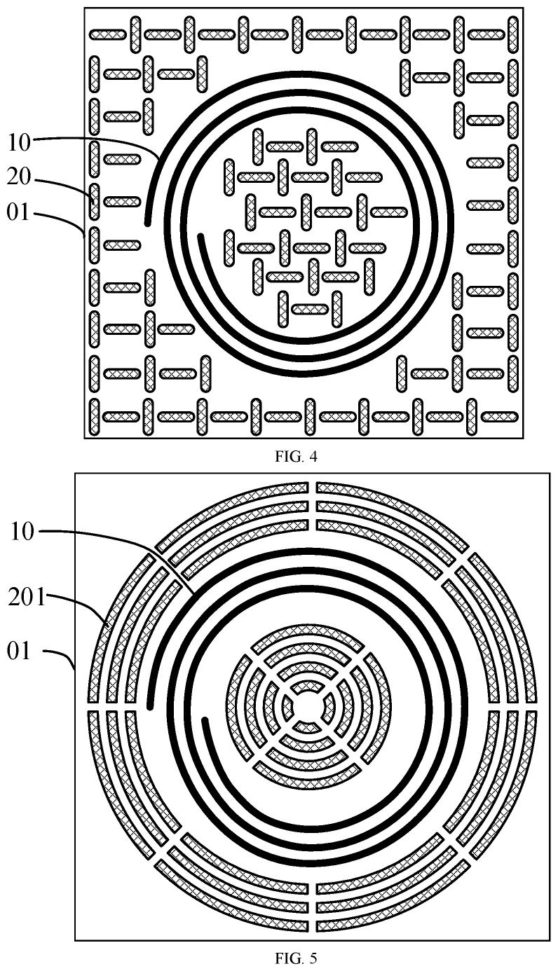

In some embodiments, FIG. 3 is a schematic diagram of another coil structure according to the embodiments of the present disclosure, as shown in FIG. 3, in the coil structure, the region in which the coil portion 10 is located is a second region Q2, a first sub-region of the second region Q2 is defined between adjacent turns of the coil portion 10, and the first pattern 20 is provided in the first sub-region, the first region Q1, and the third region Q3. In this way of disposing the first pattern 20, the space of the dielectric substrate 01 is maximumly utilized and a dielectric substrate 01 with a larger stretchability amount is acquired.

In some embodiments, as shown in FIG. 3, the coil portion 10 of the coil structure has an octagonal shape, each turn of the coil is wound in an octagonal shape, and for any two turns of the coil, one turn away from the geometric center of the coil portion 10 completely surrounds the other turn; and a first sub-region of the second region Q2 is defined between adjacent turns of the coil portion 10, and each of the first sub-region, the first region Q1, and the third region Q3 is provided with the first pattern 20. In the first region Q1 and the third region Q3, the first patterns 20 have two shapes of outline, and the outline of one kind of the first patterns 20 is obtained by rotating the outline of the other kind of the first patterns 20 by 90°. In some embodiments, the outline of one kind of the first patterns 20 is “-” and the outline of the other kind of the first patterns 20 is “1”. The first patterns 20 are arranged in a fashion of alternating between the above-described two shapes along the row direction and the column direction of the dielectric substrate 01; and in the first sub-region, the first patterns 20 have a plurality of outline shapes due to the fact that the distances between the adjacent turns of the coil portion 10 are small, and therefore, in the first sub-region of the second region Q2 defined between adjacent turns of the coil portion 10, the outline shapes of the first patterns 20 are parallel to the parallel regions defined between adjacent turns, such that the coil portion 10 is avoided when forming the first pattern 20 and adverse effects on the electrical properties of the coil portion 10 is avoided.

In some embodiments, the spacings between adjacent turns of the coil portion 10 are equal, so that in the case that the coil structure is subjected to a tension force, the coil portion 10 can be uniformly stressed, and no wire breakage caused by a sudden change of stress at a specific position will occur, thus protecting the coil portion 10, and thus ensuring the electrical performance of the coil structure.

It is noted that in the case that the first pattern 20 is provided in the first sub-region, the outline shape of the first pattern 20 is adapted to the shape of the first sub-region of the second region Q2 defined between adjacent turns of the coil portion 10. In some embodiment, in the case that the coil portion 10 of the coil structure has a square shape, the first patterns 20 have two kinds of outline shapes as shown in FIG. 1, and the outline of one kind of the first patterns 20 is obtained by rotating the outline of the other kind of the first patterns 20 by 90°. In some embodiments, the outline of one kind of the first patterns 20 is “-” and the outline of the other kind of the first patterns 20 is “1”. The first patterns 20 are arranged in parallel, respectively in the two shapes described above, along the row direction and the column direction of the dielectric substrate 01.

In some embodiments, the coil portion 10 includes at least one of a square shape, a hexagonal shape, an octagonal shape, and a circular shape. FIG. 4 is a schematic diagram of another coil structure according to the embodiments of the present disclosure; as shown in FIGS. 1, 3, and 4, the coil portions 10 have a square shape, an octagonal shape, and a circular shape, respectively.

Specifically, in FIG. 1, each turn of the coil is wound in a square shape; in FIG. 3, each turn of the coil is wound in an octagonal shape; and in FIG. 4, each turn of the coil is wound in a circular shape. In the present disclosure, the shape of the coil portion 10 is not limited. In some embodiments, the coil portion 10 has one of a variety of geometrical shapes, such as a square shape, hexagonal shape (not shown in the drawings), octagonal shape, circular shape, etc., i.e., the number of the coil portion 10 is one. In some embodiments, the shape of the coil portion is any one or more of the variety of shapes aforementioned, i.e., the number of the coil portions 10 is multiple. In some embodiments, the shape of the coil portion 10 is any one of the above-mentioned shapes, but the number of the coil portions 10 is multiple, i.e., the multiple coil portions 10 have the same shape.

Understandably, any of the above coil portions 10 and their deformations or combinations should aim at enhancing the deformation resistance of the coil structure.

In some embodiments, the shape of the coil portion 10 is a central symmetric figure, e.g., a rectangle, a regular polygon, etc. In this way, in the case that the coil structure is subjected to a tensile force, the inner stress in the dielectric substrate 01 can be uniformly dispersed, and at the same time, no wire breakage due to sudden change of stress at a specific position will occur, thus protecting the coil portion 10, and thus ensuring the electrical performance of the coil structure.

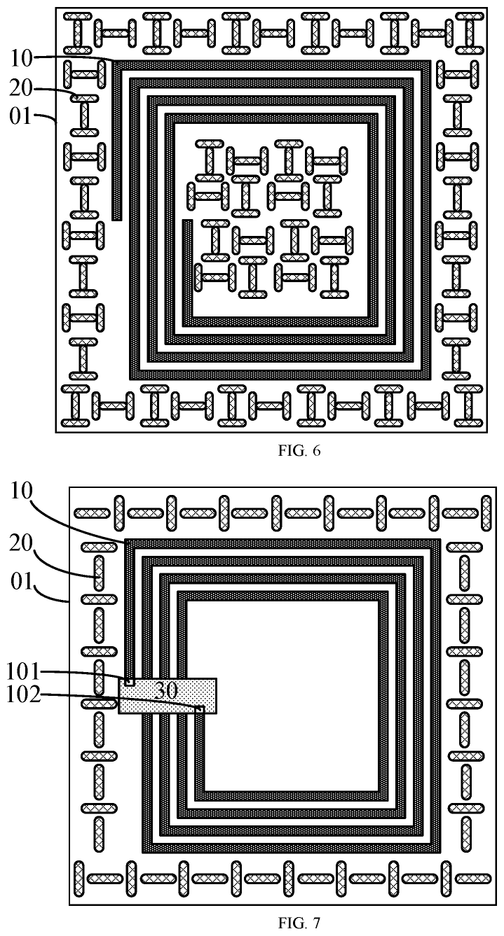

In some embodiments, FIG. 5 is a schematic diagram of another coil structure according to the embodiments of the present disclosure; FIG. 6 is a schematic diagram of another coil structure according to the embodiments of the present disclosure. As shown in FIGS. 1, 6, and 5, the outline shapes of the first pattern 20 are respectively a linear shape, an I shape, and a circular arc shape.

Specifically, in the present disclosure, the outline shape of the first pattern 20 is not limited. In some embodiments, the outline of the first pattern 20 has a linear shape as shown in FIG. 1, or the outline of the first pattern 20 has an I shape as shown in FIG. 6, or the outline of the first pattern 20 has a circular arc shape as shown in FIG. 5. In some embodiments, the outline of the first pattern 20 has any one of a variety of geometrical shapes, such as the linear shape, the I shape, and the circular arc shape, i.e., there is only one kind of outline shape for the first pattern 20. In some embodiments, the outline shapes of the first patterns 20 include any multiple shapes of the above shapes, i.e., there are multiple outline shapes for the first pattern 20. In some embodiments, the outline of the first pattern 20 has any one of the above shapes, but different shapes can be acquired based on the outline shape in some ways, such as by rotating the outline shape by a specific number of degrees. In some embodiments, as shown in FIG. 1, in the coil structure, the outline of the first pattern 20 has actually a linear shape, but two kinds of outline shapes of the first patterns 20 can be acquired by rotating the outline shape by ninety degrees clockwise/counterclockwise, i.e., “-” and “1”, respectively.

It is understandable that the outline shapes of any of the above-described first patterns 20 and the deformations or combinations thereof should be aimed at enhancing the deformation resistance of the coil structure.

In some embodiments, the outline shape of the first pattern 20 is a central symmetric figure. In this way, in the case that the coil structure is subjected to a tension force, the inner stress in the dielectric substrate 01 can be evenly dispersed, and at the same time, no wire breakage caused by a sudden change of stress at a specific position will occur, thus protecting the coil portion 10, and thus ensuring the electrical performance of the coil structure.

In some embodiments, as shown in FIG. 1 and FIG. 6, the coil structure includes first patterns 20 having two shapes of outline, which are respectively a first shape and a second shape; and the first patterns 20 are arranged in a fashion of alternating between the first shape and the second shape along the row direction and the column direction of the dielectric substrate 01.

Specifically, as shown in FIG. 1, the outline shape of the first pattern 20 is actually a linear shape, but the first patterns 20 having two kinds of outline shapes are finally acquired by rotating the outline shape by ninety degrees clockwise/counterclockwise, i.e., the first shape “-” and the second shape “1”, respectively. Further, the first patterns 20 are arranged, in a fashion of alternating between the above two shapes, along the row direction and the column direction of the dielectric substrate 01. Similarly, as shown in FIG. 6, the outline shape of the first pattern 20 is actually an I shape, but the first patterns 20 having two kinds of outline shapes are finally acquired by rotating the outline shape by ninety degrees clockwise/counterclockwise, i.e., a first shape “I” and a second shape “H”, respectively. Further, the first patterns 20 are arranged, in a fashion of alternating between the above-described two shapes, along the row direction and the column direction of the dielectric substrate 01.

In some embodiments, as shown in FIG. 5, in the coil structure, the coil portion 10 has a circular shape; and the first pattern 20 includes a plurality of first sub-patterns 201 arranged sequentially along a clockwise direction, wherein an outline of the first sub-pattern 201 has a circular arc shape, and the plurality of first sub-patterns 201 are concentric. As shown in FIG. 5, each turn of the coil portion 10 is wound in a circular shape, and a plurality of first sub-patterns 201 with circular arc shaped outlines together form a first pattern 20, the first pattern 20 being circular.

In some embodiments, a plurality of the first patterns 20 are arranged, and the first sub-patterns 201 of different first patterns 20 are disposed in one-to-one correspondence. In some embodiments, each first pattern 20 contains a same number of first sub-patterns 201; the first sub-patterns 201 of the various first patterns 20 are divided into a plurality of groups sequentially disposed along a circumferential direction of an outline of any one of the first patterns 20, and in each group of the first sub-patterns 201, the first sub-patterns 201 of the different first patterns 20 are arranged sequentially along a radial direction of the outline of any one of the first patterns 20. In this way, in the case that the coil structure is subjected to a tensile force, the first patterns 20 can absorb the tensile force uniformly, and at the same time, the preparation is simple and the process cost is reduced.

In some embodiments, as shown in FIG. 5, in the first region Q1 of the dielectric substrate 01, each first pattern 20 includes four first sub-patterns 201, and the outline of the first sub-pattern 201 has a circular arc shape; and in the third region Q3 of the dielectric substrate 01, each first pattern 20 includes eight first sub-patterns 201. In the first region Q1 of the dielectric substrate 01, the first sub-patterns 201 of the four first patterns 20 are divided into four groups that are arranged sequentially along a circumferential direction of an outline of any one of the first patterns 20, and in each group of first sub-patterns 201, the first sub-patterns 201 of different first patterns 20 are arranged sequentially along a radial direction of an outline of any one of the first patterns 20. In the third region Q3 of the dielectric substrate 01, the first sub-patterns 201 of the three first patterns 20 are divided into eight groups that are arranged sequentially along a circumferential direction of an outline of any one of the first patterns, and in each group of first sub-patterns 201, the first sub-patterns 201 of the different first patterns 20 are sequentially arranged along a radial direction of an outline of any one of the first patterns 20. Of course, it is understandable that in some embodiments the arc lengths of the first sub-patterns 201 are equal or unequal.

In some preferred embodiments, the arc lengths of the first sub-patterns 201 are equal. In this way, in the case that the coil structure is subjected to a tension force, the inner stress in the dielectric substrate 01 can be evenly dispersed by the first pattern 20.

The plurality of first patterns 20 are sequentially nested on the dielectric substrate 01 in an order of radii from small to large and are concentric with the coil portion 10, such that the inner stress of the dielectric substrate 01 is evenly dispersed, and at the same time, no wire breakage caused by a sudden change of stress at a specific position will occur, thus protecting the coil portion 10, and thus ensuring the electrical performance of the coil structure.

In some preferred embodiments, in the case that the plurality of first patterns 20 are sequentially nested on the dielectric substrate 01 in the order of the radii from small to large, the spacing distances between any two adjacent first patterns 20 are equal, thereby further ensuring that force subjected by the dielectric substrate 01 is uniform.

In some embodiments, FIG. 7 is a schematic diagram of another coil structure according to the embodiments of the present disclosure. As shown in FIG. 7, a light-emitting device 30 is also included in the coil structure; and the coil portion 10 has a first connecting end 101 and a second connecting end 102, wherein the first connecting end 101 is connected to a first electrode 03 of the light-emitting device 30, and the second connecting end 102 is connected to a second electrode 04 of the light-emitting device 30. It is to be noted that the embodiments of the present disclosure are illustrated by taking the example that the first electrode 03 is the anode of the light-emitting device 30 and the second electrode 04 is the cathode of the light-emitting device 30, which are not repeated hereinafter.

According to Faraday's law of electromagnetic induction, an induced electromotive force is generated in the case that a time-varying magnetic field passes through a closed space. Therefore, in the case that the coil structure of the present disclosure is placed in the time-varying magnetic field, the magnetic field is coupled to the coil portion 10 of the coil structure of the present disclosure, and the coils of the coil portion 10 generate voltage energy, thereby realizing its electrical properties for energy and signal transmission and in the meantime illuminating the light-emitting device 30.

Specifically, the light-emitting device 30 in the coil structure can serve as a cue. In the case that the coil structure of the present disclosure receives a current to operate, the light-emitting device 30 is simultaneously illuminated, which can prompt the user that the coil structure is working properly.

It is noted that the light-emitting devices 30 of the present disclosure include, but are not limited to, Organic Electroluminescence Diode (OLED) display devices, as long as they can achieve the function of prompt.

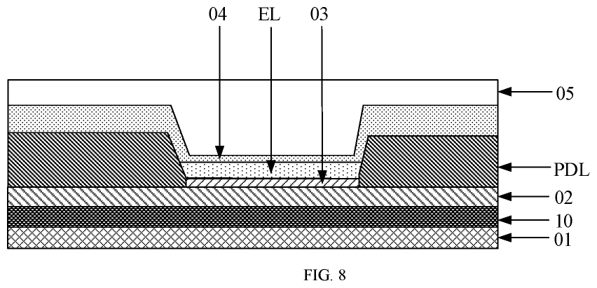

In some embodiments, FIG. 8 is a schematic diagram of the light-emitting device in an embodiment of the present disclosure, and as shown in FIGS. 7 and 8, the coil structure further includes an insulating layer 02 and a pixel-definition layer PDL that are sequentially disposed on a side, distal from the dielectric substrate 01, of the coil portion 10, wherein the pixel-definition layer PDL has an accommodation portion. The insulating layer 02 is provided to spacing the light-emitting device 30 from the coil portion 10, thereby ensuring that the functions of the light-emitting device 30 and the coil portion 10 are not affected. The light-emitting device 30 includes a first electrode 03, a light-emitting layer EL, and a second electrode 04; wherein the first electrode 03 is disposed on a side, distal from the coil portion 10, of the insulating layer 02, the light-emitting layer EL is disposed on the side, distal from the insulating layer 02, of the first electrode 03 and at least located within the accommodation portion of the pixel-definition layer PDL, and the second electrode 04 is disposed on the side, distal from the first electrode 03, of the light-emitting layer EL. The first connecting end 101 is connected to the first electrode 03 through a first via hole (not shown in the figure), and the second connecting end 102 is connected to the second electrode 04 through a second via hole (not shown in the figure); wherein the first via hole passes through the insulating layer 02, and the second via hole passes through the insulating layer 02 and the pixel-definition layer PDL.

The light-emitting device 30 further includes an encapsulation layer 05. The encapsulation for the light-emitting device 30 by the encapsulation layer 05 can effectively resist water and oxygen erosion, thereby avoiding the case that the light-emitting device 30 is incapable of prompting due to the failure of the light-emitting layer EL, and lengthening the service life of the light-emitting device 30.

In some embodiments, any one of the coil structures of the present disclosure includes the light-emitting device 30, and the position and number of the light-emitting device 30 are not limited in the present disclosure. For ease of description and understanding, the following is illustrated by taking an example of a coil structure with the light-emitting device 30 as shown in FIG. 8.

Specifically, the pixel-definition layer PDL is provided with an accommodation portion to form the light-emitting layer EL and ensure that the light-emitting layer EL can be connected to the first electrode 03 through the accommodation portion. The first via hole runs through the insulating layer 02 so that the first connecting end 101 of the coil portion 10 is connected to the first electrode 03 through the first via hole, and the second via hole runs through the insulating layer 02 and the pixel-definition layer PDL so that the second connecting end 102 of the coil portion 10 is connected to the second electrode 04 through the second via hole, thereby forming a complete circuit between the light-emitting device 30 and the coil portion 10. Therefore, in the case that the coil portion 10 is in a time-varying magnetic field and generates an induced electromotive force and the voltage difference on the coil portion 10 reaches the illumination voltage of the light-emitting device 30, the light-emitting device 30 is illuminated, thereby achieving the prompting function of the light-emitting device 30, that is, the function of an indicator light.

In some preferred embodiments of the present disclosure, the light-emitting device 30 is an OLED display device. Because the OLED display device has the characteristics of self-illumination, high luminance, high contrast, and low operating voltage, and is applicable to make flexible displays, the OLED display device is more suitable for the coil structure of the present disclosure.

In some embodiments, the first pattern 20 runs through the dielectric substrate 01 along the thickness direction of the dielectric substrate 01. In the case that the coil structure according to the embodiments of the present disclosure includes the light-emitting device 30, the coil structure further includes an insulating layer 02 disposed on the side, distal from the dielectric substrate 01, of the coil portion 10, and the first pattern 20 runs through the insulating layer 02 while running completely through the dielectric substrate 01 along the thickness direction of the dielectric substrate 01.

The first pattern 20 runs through the insulating layer 02 while completely running through the dielectric substrate 01 along the thickness direction of the dielectric substrate 01, which allows for a greater stretchability amount of the dielectric substrate 01. In the case that the coil structure is subjected to a tensile force, the inner stress of the dielectric substrate 01 can be evenly dispersed, and at the same time, no wire breakage caused by a sudden change of stress at a specific position will occur, thereby protecting the coil portion 10 and thus ensuring the electrical performance of the coil structure.

In some embodiments, the coil structure is a near field communication (NFC) antenna or a charging coil. In the case that the coil structure is an NFC antenna, the coil structure can be considered as a coupling coil. According to Ampere's law, a magnetic field is generated around a conductor in the case that an electric current flows through a wire, wherein the intensity of the induced magnetic field is proportionate to the number of turns and the area of the coil, and decays with the third power of the distance. According to Faraday's law of electromagnetic induction, a time-varying magnetic field passing through a closed space induces an electromotive force. Therefore, these two laws are respectively applied to the NFC reader and NFC card, wherein the NFC reader antenna generates a magnetic field coupled to the NFC card antenna to generate voltage energy, which activates the chip in the NFC card, and thus energy and signal transmission takes place.

In the case that the coil structure is a charging coil, the coil structure can be mainly applied to wireless charging. The principle of electromagnetic induction wireless charging is similar to the principle of a transformer, which uses the generated magnetic field to transfer energy based on the coils mounted respectively on the charging base and the receiving device. In the case that a sinusoidal alternating current is applied to the power transmission coil on the charging base, a current is induced in the neighboring receiving coil, thereby ultimately achieving the charging for the cell phone battery. It is understandable that in the case that the coil structure is a charging coil, the coil structure can be applied not only in the field of consumer electronics, but also in more different fields, such as smart home systems, industrial systems, etc.

According to a second aspect, the embodiments of the present disclosure further provide an electronic device including a coil structure as described above, and a functional device disposed on the coil structure. In some embodiments of the present disclosure, the electronic device includes an LCD display panel, or includes an OLED display panel or a flexible display. The electronic device provided in the embodiments of the present disclosure includes, but is not limited to, a cell phone, an electronic bracelet, an electronic watch, a tablet computer, an in-vehicle device, an augmented reality (AR) device, a virtual reality (VR) device and the like.

It is understandable that the above embodiments are merely exemplary embodiments to illustrate the principles of the present invention, the present disclosure is not limited thereto. For a person of ordinary skill in the art, various variations and improvements may be made without departing from the concept and substance of the present disclosure, which are also considered to be within the scope of protection of the present disclosure.

1. A coil structure, comprising:
a dielectric substrate; and
a coil portion and a first pattern disposed on the dielectric substrate;
wherein the first pattern extends through at least a portion of the dielectric substrate along a thickness direction of the dielectric substrate, and the first pattern is not overlapped with the coil portion.

2. The coil structure according to claim 1, wherein the dielectric substrate comprises a first region, a second region, and a third region, the second region surrounding the first region, and the third region surrounding the second region;
wherein the coil portion is disposed in the second region, and the first pattern is arranged in both the first region and the third region.

3. The coil structure according to claim 2, wherein a first sub-region of the second region is defined between adjacent turns of the coil portion, and the first pattern is arranged in the first sub-region.

4. The coil structure according to claim 1, wherein the coil portion has at least one of a square shape, a hexagonal shape, an octagonal shape, or a circular shape.

5. The coil structure according to claim 1, wherein an outline of the first pattern has at least one of a linear shape, an I shape, or a circular arc shape.

6. The coil structure according to claim 1, further comprising first patterns with two shapes of outline which are respectively a first shape and a second shape, wherein the first patterns are arranged in a fashion of alternating between the first shape and the second shape along a row direction and a column direction of the dielectric substrate.

7. The coil structure according to claim 1, wherein the coil portion has a circular shape; wherein
the first pattern comprises a plurality of first sub-patterns arranged sequentially along a clockwise direction, wherein an outline of the first sub-pattern has a circular arc shape, and the plurality of first sub-patterns are concentric.

8. The coil structure according to claim 7, wherein a plurality of the first patterns are arranged, and the first sub-patterns of different first patterns are disposed in one-to-one correspondence.

9. The coil structure according to claim 1, further comprising: a light-emitting device;
wherein the coil portion comprises a first connecting end and a second connecting end, the first connecting end being connected to a first electrode of the light-emitting device, and the second connecting end being connected to a second electrode of the light-emitting device.

10. The coil structure according to claim 9, further comprising: an insulating layer and a pixel-definition layer that are sequentially disposed on a side, distal from the dielectric substrate, of the coil portion, the pixel-definition layer having an accommodation portion;
the light-emitting device comprises the first electrode, a light-emitting layer, and the second electrode, wherein the first electrode is disposed on a side, distal from the coil portion, of the insulating layer, the light-emitting layer is disposed on a side, distal from the insulating layer, of the first electrode and is positioned at least within the accommodation portion of the pixel-definition layer, and the second electrode is positioned on a side, distal from the first electrode, of the light-emitting layer; and
the first connecting end is connected to the first electrode through a first via hole, and the second connecting end is connected to the second electrode through a second via hole; wherein the first via hole runs through the insulating layer, and the second via hole runs through the insulating layer and the pixel-definition layer.

11. The coil structure according to claim 10, wherein the first pattern runs through the dielectric substrate along a thickness direction of the dielectric substrate.

12. The coil structure according to claim 1, wherein the coil structure is a near field communication antenna or a charging coil.

13. An electronic device, comprising: a coil structure and a functional device disposed on the coil structure;
wherein the coil structure, comprises: a dielectric substrate; and a coil portion and a first pattern disposed on the dielectric substrate; wherein the first pattern extends through at least a portion of the dielectric substrate along a thickness direction of the dielectric substrate, and the first pattern is not overlapped with the coil portion.

14. The electronic device according to claim 13, wherein the dielectric substrate comprises a first region, a second region, and a third region, the second region surrounding the first region, and the third region surrounding the second region;
wherein the coil portion is disposed in the second region, and the first pattern is arranged in both the first region and the third region.

15. The electronic device according to claim 14, wherein a first sub-region of the second region is defined between adjacent turns of the coil portion, and the first pattern is arranged in the first sub-region.

16. The electronic device according to claim 13, wherein the coil portion has at least one of a square shape, a hexagonal shape, an octagonal shape, or a circular shape.

17. The electronic device according to claim 13, wherein an outline of the first pattern has at least one of a linear shape, an I shape, or a circular arc shape.

18. The electronic device according to claim 13, wherein the coil structure further comprises first patterns with two shapes of outline which are respectively a first shape and a second shape, wherein the first patterns are arranged in a fashion of alternating between the first shape and the second shape along a row direction and a column direction of the dielectric substrate.

19. The electronic device according to claim 13, wherein the coil portion has a circular shape; wherein
the first pattern comprises a plurality of first sub-patterns arranged sequentially along a clockwise direction, wherein an outline of the first sub-pattern has a circular arc shape, and the plurality of first sub-patterns are concentric.

20. The electronic device according to claim 19, wherein a plurality of the first patterns are arranged, and the first sub-patterns of different first patterns are disposed in one-to-one correspondence.
